(19) United States
(12) Patent Application Publication
(10) Pub. No.: US 2026/0006877 A1
(43) Pub. Date: Jan. 1, 2026

(54) SELECTIVE LASER TREATMENTS FOR TRANSITION METAL DICHALCOGENIDE BASED TRANSISTOR STRUCTURES

(71) Applicant: Intel Corporation, Santa Clara, CA (US)

(72) Inventors: Carl H. Naylor, Portland, OR (US); Christopher Jezewski, Portland, OR (US); Matthew Metz, Portland, OR (US); Uygar Avci, Portland, OR (US); Kevin P. O’Brien, Portland, OR (US); Scott B. Clendenning, Portland, OR (US); Ashish Verma Penumatcha, Hillsboro, OR (US); Arnab Sen Gupta, Hillsboro, OR (US); Kirby Maxey, Hillsboro, OR (US); Eric Mattson, Portland, OR (US); Mahmut Sami Kavrik, Hillsboro, OR (US); Azimkhan Kozhakhmetov, Hillsboro, OR (US); Chelsey Dorow, Portland, OR (US)

(73) Assignee: Intel Corporation, Santa Clara, CA (US)

(21) Appl. No.: 18/759,046

(22) Filed: Jun. 28, 2024

(51) Int. Cl. H01L 29/18; H01L 27/092; H01L 29/06; H01L 29/423; H01L 29/778; H01L 29/786

(52) U.S. Cl. CPC H10D 62/84; H10D 30/47; H10D 30/6735; H10D 30/6757; H10D 62/118; H10D 84/85

(57) ABSTRACT

Devices, transistor structures, systems, and techniques are described herein related to field effect transistors having a stack of metal chalcogenide nanoribbons extending between a source and drain and contacted by a gate structure. The metal chalcogenide nanoribbons may be recrystallized using a local laser anneal treatment and/or a dopant may be applied, outside of a channel region of the metal chalcogenide nanoribbons, using a local laser treatment in the presence of a precursor including the dopant.

### BACKGROUND

Higher performance, lower cost, increased miniaturization, and greater density of integrated circuits (ICs) are ongoing goals of the electronics industry. To maintain the pace of increasing transistor density, for example, device dimensions must continue to shrink. 2D materials such as transition metal dichalcogenides (TMDs) have the potential to achieve advanced scaling of transistors such as gate-all-around (GAA) or nanoribbon transistors. However, difficulties in the deployment of 2D materials remain, including contact resistance and achieving high quality 2D materials in the transistor structure. It is with respect to these and other considerations that the present improvements have been needed. Such improvements may become critical as the desire to deploy 2D materials in transistor structures becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a transistor structure having recrystallized 2D material layers and/or doped edges of the 2D material layers;

FIGS. 2, 3, 4, 5, 6, 7, 8, 9, 10, 12, 13, 14, 15, and 16 are cross-sectional views of transistor structures having recrystallized 2D material layers and/or doped edges of the 2D material layers evolving as methods are practiced;

FIGS. 11A, 11B, 11C, 11D, and 11E are isometric views of transistor structures illustrating alternative 2D material layer formation and resultant grain boundary densities evolving as methods are practiced;

FIG. 17 illustrates exemplary systems employing metal chalcogen material-based transistor structures having recrystallized 2D material layers and/or doped edges of the 2D material layers; and

FIG. 18 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to applying local laser treatments to transition metal dichalcogenide layers to recrystallize the transition metal dichalcogenide layers and/or to dope the transition metal dichalcogenide layers outside of the channel region.

As discussed, transition metal dichalcogenide (TMD) materials or similar materials, which may be referred to as 2D materials, may be deployed as the semiconductor in a transistor structure such as a gate-all-around (GAA), dual gate, or nanoribbon transistor. For example, 2D material layers may be deployed as a stack of separated nanoribbons in a transistor. Current difficulties in the deployment of 2D materials include contact resistance to the source and drain and the need for high quality 2D materials. With respect to contact resistance, doping the edges of the 2D materials can improve contact resistance. For the issue of high quality TMD material layers, anneal processing of the 2D material, and in particular, the channel region of the 2D material can improve material quality by reducing defects such as grain boundaries.

The techniques discussed herein offer such edge doping and recrystallization efficiently, without multiple steps and integrated into a process flow. In some embodiments, localized laser treatment can be used to provide edge doping and/or recrystallization anneal. As used herein, the term localized laser treatment indicates application of a laser to effect a local change in the transistor structure. The localized laser treatment can be applied across a workpiece (such as a wafer) or only locally in a discrete area including the transistor structures (without application to regions not including transistor structures). The localized laser treatment for recrystallization anneal reduces defects and improves 2D material quality and therefore transistor performance. The localized laser treatment for doping, performed in the presence of a dopant precursor, dopes exposed portions of the 2D material to reduce contact resistance and therefore improve transistor performance. Such techniques may be used together or separately to fabricate improved 2D material-based transistors.

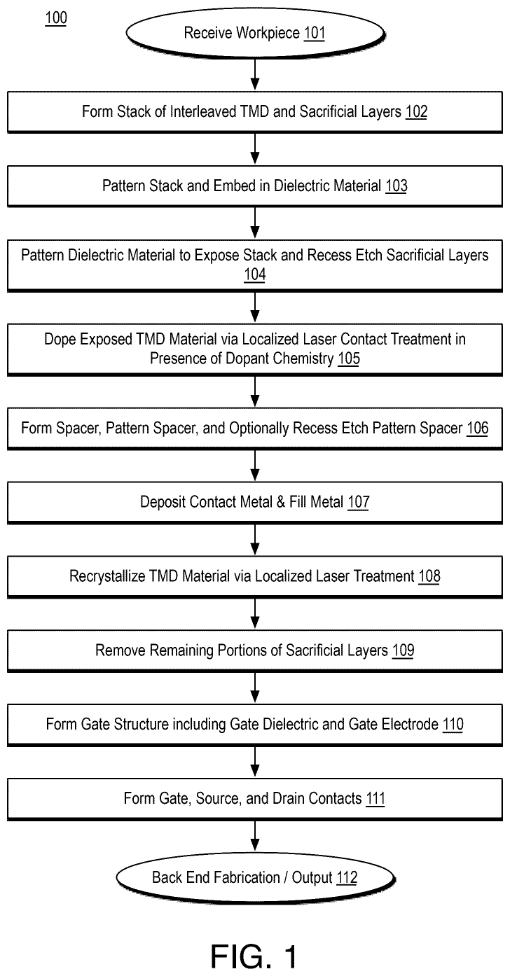

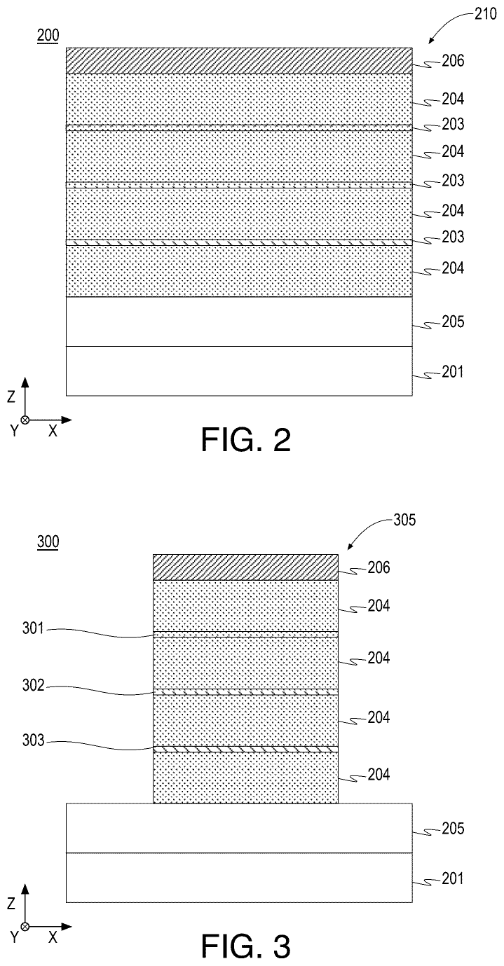

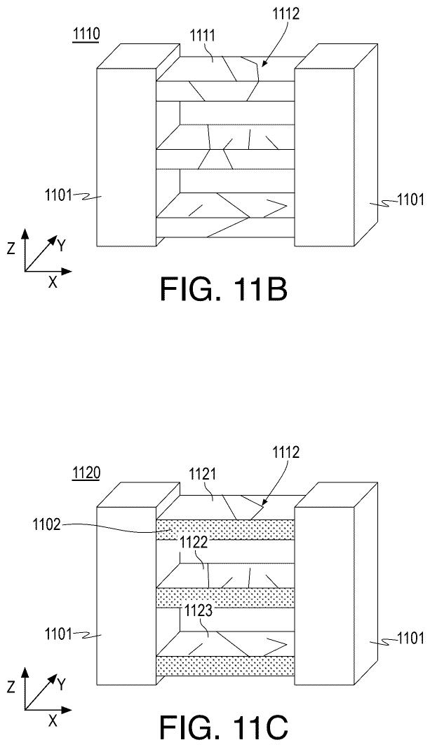

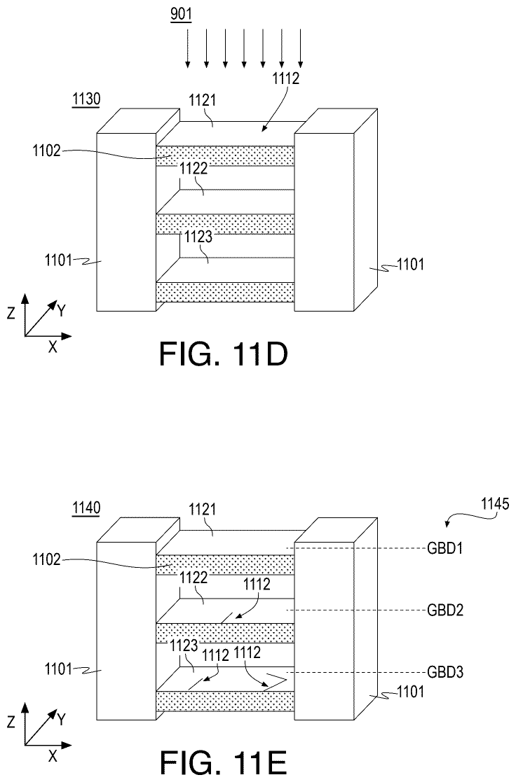

FIG. 1 is a flow diagram illustrating methods 100 for forming a transistor structure having recrystallized 2D material layers and/or doped edges of the 2D material layers, arranged in accordance with some embodiments of the disclosure. Methods 100 may be practiced, for example, to fabricate any transistor structure discussed herein. FIGS. 2, 3, 4, 5, 6, 7, 8, 9, 10, 12, 13, 14, 15, and 16 are cross-sectional views of transistor structures having recrystallized 2D material layers and/or doped edges of the 2D material layers evolving as methods 100 are practiced, arranged in accordance with some embodiments of the disclosure. FIGS. 11A, 11B, 11C, 11D, and 11E are isometric views of transistor structures illustrating alternative 2D material layer formation and resultant grain boundary densities evolving as methods 100 are practiced, arranged in accordance with some embodiments of the disclosure.

Methods 100 begin at input operation 101, where a workpiece is received for processing. For example, a substrate such as a wafer substrate workpiece may be received for processing. The substrate may include an optional dielectric layer or etch stop layer, in some embodiments. Processing continues at operation 102, where a multilayer stack is formed. The multilayer stack includes a number of material layers (e.g., metal chalcogen layers) interleaved with sacrificial layers. An optional hard mask layer may be formed over the interleaved layers. The materials of the multilayer stack may be formed using any suitable technique or techniques such as deposition techniques including atomic layer deposition (ALD), chemical vapor deposition (CVD), physical vapor deposition (PVD) such as evaporation or sputter deposition, plasma enhanced chemical vapor deposition (PECVD), or metal-organic chemical vapor deposition (MOCVD) by layer transfer techniques. In some embodiments, the sacrificial layers are formed using CVD and the material layers are formed using MOCVD.

FIG. 2 illustrates a cross-sectional side view of a transistor structure 200 including a multilayer stack 210 formed over a substrate 201 and optional dielectric layer 205. As shown, multilayer stack 210 includes of a number of material layers 203 interleaved with a number of sacrificial layers 204. Also as shown, multilayer stack 210 includes an optional hardmask layer 206. As illustrated below, a GAA transistor, dual gate transistor, or nanoribbon transistor may include a stack of nanoribbons such as metal chalcogen layers that extend from a source structure to a drain structure, with the stack of nanoribbons being formed from material layers 203. Although illustrated with three material layers 203, transistor structure 200 may include any number of material layers 203 to fabricate any number of nanoribbons such as four to six nanoribbons, or more. Furthermore, although discussed with respect to metal chalcogen materials in some contexts such that material layers 203 include a metal and a chalcogen, material layers 203 may be any suitable material such as a 2D material. Material layers 203 may have any suitable thicknesses. In some embodiments, material layers 203 each have a thickness of not more than 1 nm. In some embodiments, material layers 203 each have a thickness of about 0.33 nm.

As shown, transistor structure 200 includes substrate 201 and optional dielectric layer 205. Substrate 201 may include any suitable material or materials. For example, substrate 201 may be a substrate substantially aligned along a predetermined crystal orientation (e.g., <100>, <111>, <110>, or the like). In some embodiments, substrate 201 is a semiconductor material such as monocrystalline silicon (Si), germanium (Ge), silicon germanium (SiGe), a III-V materials-based material (e.g., gallium arsenide (GaAs)), a silicon carbide (SiC), a sapphire (Al₂O₃), or any combination thereof. In some embodiments, substrate 201 is silicon having a <111> crystal orientation. In various embodiments, substrate 201 may include metallization interconnect layers for integrated circuits or electronic devices such as transistors, memories, capacitors, resistors, optoelectronic devices, switches, or any other active or passive electronic devices separated by an electrically insulating layer, for example, an interlayer dielectric, a trench insulation layer, or the like. Optional dielectric layer 205 may act as an etch stop and may include any suitable material such as silicon oxide, silicon nitride, or silicon carbide.

In some embodiments, one or more of material layers 203 are metal chalcogen layers that each includes a transition metal and a chalcogen. The transition metal may be any transition metal such as any element of groups 4 through 11, the group 3 elements scandium and yttrium, and the inner transition metals (e.g., f-block lanthanide and actinide series). The chalcogen may be any chalcogen such as group 16 elements, excluding oxygen. Notably advantageous transition metals are molybdenum and tungsten. Notably advantageous chalcogens are sulfur, selenium, and tellurium. In some embodiments, one or more of material layers 203 are stoichiometric TMDs. For example, one or more of material layers 203 (e.g., metal chalcogen layers) may be MoS₂, WS₂, MoSe₂, WSe₂, MoTe₂, or WTe₂. In some embodiments, one or more of material layers 203 is a molecular monolayer (e.g., a monolayer of a transition metal and a chalcogen). In some embodiments, the molecular monolayer includes an atomic center transition metal layer and atomic chalcogen layers on both sides of the atomic center transition metal layer. In some embodiments, the molecular monolayer has a thickness of about 0.33 nm.

Although discussed with respect to a metal chalcogen layer or a TMD layer, in some contexts, material layers 203 may be a 2D material layer such as a monolayer. For example, one or more of material layers 203 may be a monolayer sheet, a 2D channel material, a nanosheet, or a nanoribbon. In some embodiments, material layers 203 may be semiconductor materials. In some embodiments, each of material layers 203 include multiple stacked monolayer sheets. In some embodiments, one or more of material layers 203 is a graphene-based (or graphene family) material such as graphene, hexagonal boron nitride (hBN, white graphene), boron and nitrogen co-doped graphene (BCN), fluorographene, or graphene oxide. In some embodiments, one or more material layers 203 is a semiconducting dichalcogenide including a chalcogen and a metal such as one of the TMD materials discussed above. In some embodiments, one or more of material layers 203 is one of ZrS₂ or ZrSe₂. In some embodiments, one or more of material layers 203 is a 2D oxide such as a mica or a bismuth strontium calcium copper oxide (BSCCO) including MoO₃ or WO₃. In some embodiments, one or more of material layers 203 is a 2D oxide such as a layered copper oxide including TiO₂, MnO₂, V₂O₅, TaO₃, RuO₂, or the like. In some embodiments, one or more of material layers 203 is a 2D oxide such as a perovskite-type including LaNb₂O₇, (Ca,Sr)₂Nb₃O₁₀, Bi₄Ti₃O₁₂, Ca₂Ta₂TiO₁₀, or the like. In some embodiments, one or more of the material layers 203 is a 2D oxide such as a hydroxide including Ni(OH)₂ or Eu(OH)₂ or the like.

Sacrificial layers 204 may be any material that may be etched or removed selectively with respect to material layers 203. In some embodiments, sacrificial layers 204 are one of silicon oxide (i.e., sacrificial layers 204 include silicon and oxygen), silicon nitride (i.e., sacrificial layers 204 include silicon and nitrogen), silicon oxynitride titanium oxide (i.e., sacrificial layers 204 include silicon, oxygen, and nitrogen), or aluminum oxide (i.e., sacrificial layers 204 include aluminum and oxygen; alumina). As discussed below, in some embodiments, patterned material layers 203 are recrystallized using local laser treatment. In such embodiments, it is advantageous that sacrificial layers 204 are substantially transparent or translucent to the selected wavelength of light (i.e., limited spectrum around the selected wavelength) such that the laser treatment may reach the lower ones of material layers 203 In some embodiments, silicon oxide, silicon nitride, silicon oxynitride, titanium oxide, and alumina (i.e., SiO2, SiN, SiOxNy, TiO2, and Al2O3) offer the advantages of being selectively etchable with respect to material layers 203 and being substantially transparent to the laser treatment discussed herein below. In some embodiments, hardmask layer 206 is silicon carbide. Material layers 203, sacrificial layers 204, and hardmask layer 206 may be formed using ALD, CVD, PVD, PECVD, MOCVD, or the like.

Returning to FIG. 1, processing continues at operation 103, where the multilayer stack formed at operation 102 is patterned and the patterned multilayer stack is embedded in dielectric material. The multilayer stack may be patterned using any suitable technique or techniques such as lithography and etch techniques. The dielectric material that the patterned multilayer stack is embedded in may be formed using any suitable technique or techniques such as bulk deposition of a dielectric such as silicon oxide, silicon nitride, or silicon oxynitride followed by planarization.

FIG. 3 illustrates a cross-sectional side view of a transistor structure 300 similar to transistor structure 200 after patterning multilayer stack 210 to form a patterned multilayer stack 305. In some embodiments, a patterned photoresist layer is formed on hardmask layer 206 and etch techniques are used to form the pattern of patterned multilayer stack 305. In some embodiments, the pattern of the photoresist layer is first transferred to hardmask layer 206 and then to the remainder of patterned multilayer stack 305. In some embodiments, dielectric layer 205 acts as an etch stop layer. As shown, such patterning may define metal chalcogen layers 301, 302, 303, which are part of patterned multilayer stack 305. Although discussed in some contexts with respect to metal chalcogen layers 301, 302, 303, layers 301, 302, 303 may be any materials discussed above with respect to material layers 203.

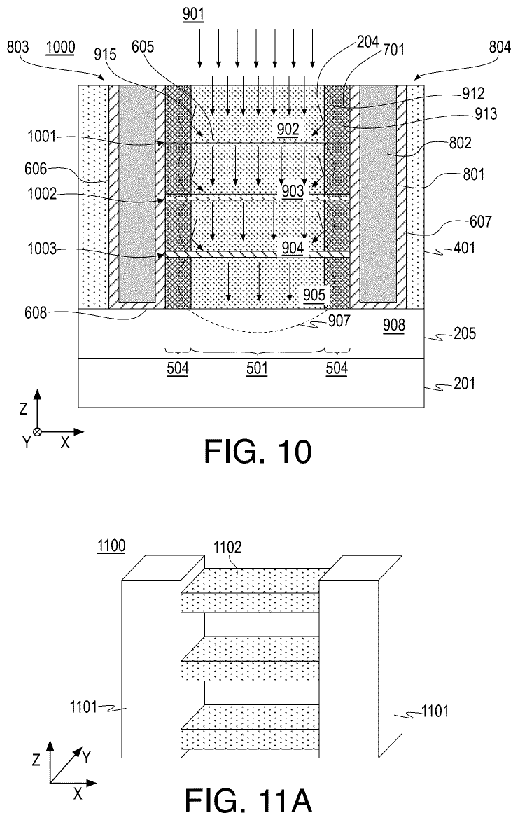

As discussed with respect to operation 108 and FIGS. 9 and 10 herein below, metal chalcogen layers 301, 302, 303 may be recrystallized using local laser treatment. It is noted that such local laser treatment may be advantageously performed as presented in methods 100 and in the corresponding sequence of transistor structures, in some embodiments. In other embodiments, the discussed local laser treatment may be performed at other points in methods 100. In some embodiments, the local laser treatment, which is discussed in greater detail below, is performed on patterned multilayer stack 305 after the removal of hardmask layer 206. Such local laser treatment may offer the advantage of greater access to metal chalcogen layers 301, 302, 303, in some contexts. Notably, metal chalcogen layers 301, 302, 303 as formed at operation 102 and patterned at operation 103 include defects such as grain boundary defects that diminish transistor performance. The local laser treatment reduces or eliminates the grain boundary defects for improved performance as discussed herein below. In some embodiments, hardmask layer 206 is removed prior to such treatment due to it being substantially opaque to the local laser treatment.

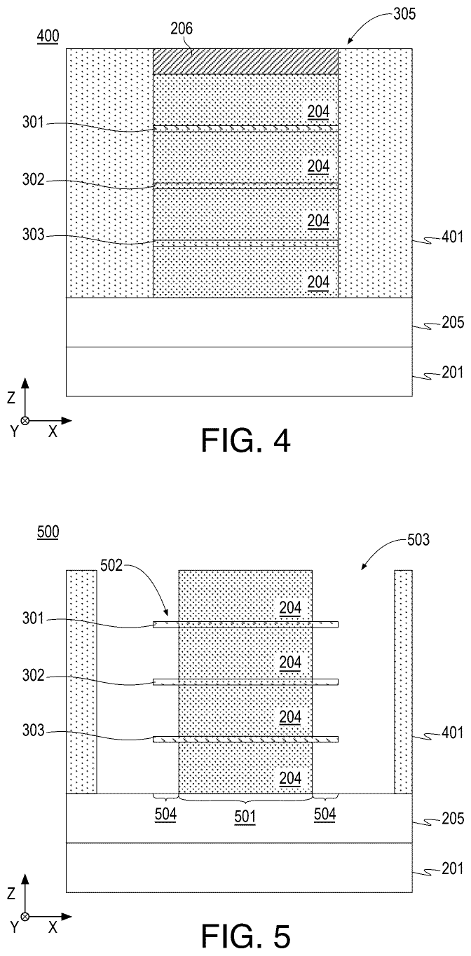

FIG. 4 illustrates a cross-sectional side view of a transistor structure 400 similar to transistor structure 300 after the formation of dielectric material 401. In some embodiments, the photoresist layer is removed and a bulk dielectric material is formed over patterned multilayer stack 305 (with or without hardmask layer 206). Planarization (e.g., chemical mechanical polishing) is then performed to expose patterned multilayer stack 305 and to embed it in dielectric material 401.

Returning to FIG. 1, processing continues at operation 104, where the dielectric material formed at operation 104 is patterned to expose the source and drain ends of the embedded multilayer stack, and a selective recess etch is performed on the sacrificial layers of the multilayer stack to expose portions of the material layers of interest. Notably, in some embodiments, the exposed portions of the material layers may be doped for improved contact resistance and conductivity characteristics as discussed herein. The dielectric material may be patterned using any suitable technique or techniques such as photolithography and etch techniques. The recess etch may be performed by selective wet etch or atomic layer etch (ALE) or the like.

FIG. 5 illustrates a cross-sectional side view of a transistor structure 500 similar to transistor structure 400 after the patterning of dielectric material 401 to form openings 503 that reveal patterned multilayer stack 305 (and, notably, source and drain ends of metal chalcogen layers 301, 302, 303), and after a recess etch exposes portions 502 of metal chalcogen layers 301, 302, 303. In some embodiments, a patterned photoresist layer is formed on the planar top surfaces of patterned multilayer stack 305 and dielectric material 401, and etch techniques are used to form openings 503. The subsequent recess etch that recesses sacrificial layers 204 to expose portions 502 of metal chalcogen layers 301, 302, 303 may include selective wet etch or ALE techniques. As shown, in some embodiment, hardmask layer 206 is removed. However, in some embodiments, hardmask layer 206 remains.

Notably, the recess etch may define channel regions 501 of metal chalcogen layers 301, 302, 303. As used herein, the term channel region indicates a region or portion of a material that is in contact with and/or under control of a gate structure. Notably, a region of a material layer need not be in operation to be characterized as a channel region, channel material, or the like. Contact regions 504 of metal chalcogen layers 301, 302, 303 are outside of channel regions 501. In some contexts, it is advantageous to dope metal chalcogen layers 301, 302, 303 outside of channel regions 501, while not doping metal chalcogen layers 301, 302, 303 in channel regions 501. For example, to maintain semiconductor properties, it may be necessary for metal chalcogen layers 301, 302, 303 to be undoped in channel region 501; however, it is desirable that metal chalcogen layers 301, 302, 303 be doped outside of channel regions 501 (i.e., in contact regions 504) for improved for improved contact resistance and conductivity.

Returning to FIG. 3, processing continues at operation 105, where the exposed regions of the material layers of interest (e.g., 2D material layers) are doped with a dopant using a localized laser treatment and a precursor including the dopant. For example, a multilayer stack including a number of material layers interleaved with a number of sacrificial layers may be fabricated or received, such that the material layers each include a transition metal and a chalcogen, as discussed above. A localized laser treatment may then be applied the multilayer stack such that the localized laser treatment includes doping an exposed region of each of the material layers using the localized laser treatment and a precursor including a dopant. The laser treatment may include application of any suitable wavelength of light (i.e., a limited spectrum around the selected wavelength) such as wavelengths 532 nm, 335 nm, or 1.6 microns. The precursor may include any suitable molecule including the dopant atom such as a molecule having a functional group bonded to the dopant atom. In presence of the localized laser treatment, the dopant atom may bond to and dope the exposed regions of the material layers of interest (e.g., the 2D material layers) while the bond to the functional group is broken and the functional group is discarded. In some embodiments, the dopant is one of ruthenium, germanium, aluminum, lanthanum, magnesium, vanadium, niobium, tantalum, manganese, rhenium, gallium, antimony, scandium, yttrium, gadolinium, molybdenum, or tungsten. In some embodiments, the functional group of the precursor is one of an acetylacetonate, amidinate, carbonyl, nitrosyl, isocyanide, or phosphine group or an alkyl, aryl, arene or cyclopentadienyl group. However, any suitable chemistry may be used.

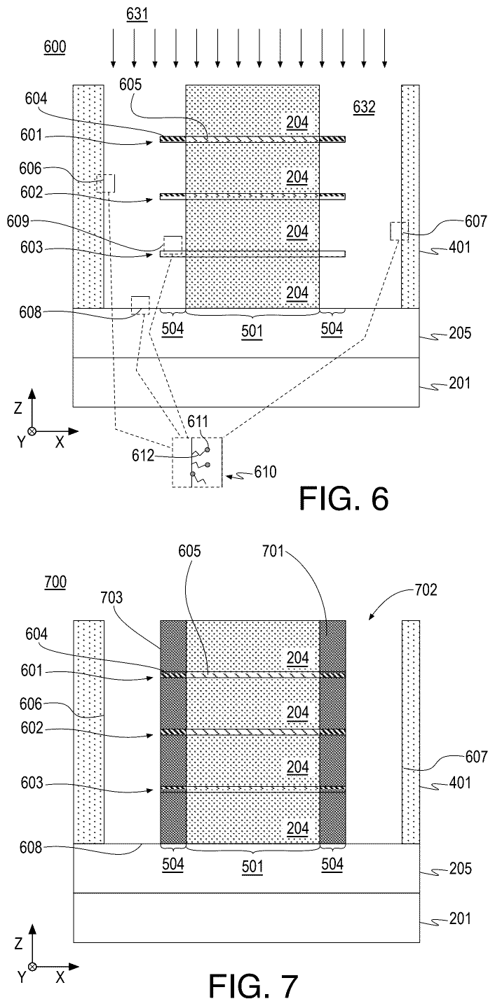

FIG. 6 illustrates a cross-sectional side view of a transistor structure 600 similar to transistor structure 500 during formation of doped regions 604 of metal chalcogen layers 601, 602, 603. As shown, localized laser treatment 631 is applied to transistor structure 600 in the presence of precursors 632 (i.e., ambient precursors). Metal chalcogen layers 601, 602, 603 then include doped regions 604 and undoped regions 605 that are within contact regions 504 and channel regions 501, respectively. As discussed, precursors 632 may include any suitable chemistry that provides for doping of doped regions 604. In some embodiments, the dopant of doped regions 604 is ruthenium, germanium, aluminum, lanthanum, magnesium, vanadium, niobium, tantalum, manganese, rhenium, gallium, antimony, scandium, yttrium, gadolinium, molybdenum, or tungsten. In some embodiments, the transition metal of metal chalcogen layers 601, 602, 603 is molybdenum or tungsten. In some embodiments, the chalcogen of metal chalcogen layers 601, 602, 603 is one of sulfur, selenium, or tellurium. In some embodiments, the transition metal of metal chalcogen layers 601, 602, 603 is molybdenum or tungsten, the chalcogen of metal chalcogen layers 601, 602, 603 is sulfur, selenium, or tellurium, and the dopant of doped regions 604 of metal chalcogen layers 601, 602, 603 is ruthenium. In some embodiments, channel regions 501 are absent the dopant of doped regions 604. The dopants of doped regions 604 may insert into defects of metal chalcogen layers 601, 602, 603 and/or displace atoms of metal chalcogen layers 601, 602, 603 such that the dopants are integrated into the 2D plane of metal chalcogen layers 601, 602, 603.

In various embodiments, the ultimate fabricated transistor structure is an n-type metal oxide semiconductor (NMOS) device or a p-type metal oxide semiconductor (PMOS) device. In some embodiments, an NMOS device and a PMOS device may be integrated in an integrated circuit (IC) device or die. Advantageously, when metal chalcogen layers 601, 602, 603 are p-type, doped regions 604 provide p-type doping and when metal chalcogen layers 601, 602, 603 are n-type, doped regions provide n-type doping. For example, n-type dopants include lanthanum, magnesium, scandium, yttrium, ruthenium, niobium, manganese, rhenium, antimony, and gadolinium. P-type dopants include germanium, aluminum, vanadium, niobium, tantalum, molybdenum, and gallium. In some embodiments, metal chalcogen layers 601, 602, 603 are n-type such as MoS₂ or WS₂ and doped regions 604 include one of lanthanum, magnesium, scandium, yttrium, ruthenium, niobium, manganese, rhenium, antimony, and gadolinium. In some embodiments, metal chalcogen layers 601, 602, 603 are p-type such as MoSe₂ or WSe₂ and doped regions 604 include one of germanium, aluminum, vanadium, niobium, tantalum, molybdenum, and gallium.

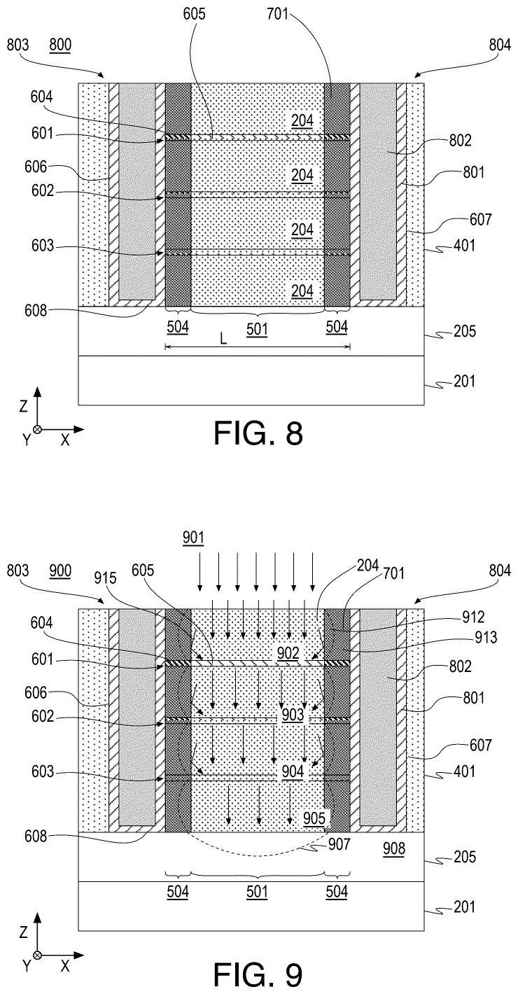

Also as shown, during the formation of doped regions 604, precursor molecules 610 may be deposited on one or more surface locations 606, 607, 608 of transistor structure 600. Precursor molecules 610 remain during subsequent processing and formation of resultant transistor structure. In some embodiments, surface location 606 is on a sidewall of dielectric material 401, and a transistor structure includes precursor molecules 610 between and on dielectric material 401 and a source structure (refer to FIG. 8). In some embodiments, surface location 607 is on a sidewall of dielectric material 401, and a transistor structure includes precursor molecules 610 between and on dielectric material 401 and a drain structure (refer to FIG. 8). In some embodiments, surface location 608 is on a surface of dielectric layer 205 (or substrate 201), and a transistor structure includes precursor molecules 610 between and on dielectric layer 205 (or substrate 201) and a source or drain structure (refer to FIG. 8). In some embodiments, surface location 609 is on a surface of doped region 604, and a transistor structure includes precursor molecules 610 between and on doped region 604 and a source or drain structure (refer to FIG. 8).

In any case, the transistor structure includes metal chalcogen layers 601, 602, 603 (i.e., material layers) each having doped regions 604 doped with a dopant absent from channel regions 501 and molecules having a dopant atom 611 bonded to a functional group 612. As shown, dopant atom 611 or functional group 612 of precursor molecules 610 may bond to a structure (e.g., dielectric layer 205 (or substrate 201) or dielectric material 401). As discussed, functional group 612 may include any suitable group to which dopant atom 611 may be bonded for delivery via precursors 632 and which may dissociate from dopant atom 611 during application of localized laser treatment 631. In some embodiments, functional group 612 is or includes one of a hexafluoroacetylacetone group, a tetramethyl-heptanedionato group, an alkyl group such as a methyl or ethyl group, a carbonyl group, a nitrosyl group, an isocyanide group, an aryl group, or a cyclopentadienyl group. In some embodiments, the transition metal of metal chalcogen layers 601, 602, 603 is or includes molybdenum or tungsten, the chalcogen of metal chalcogen layers 601, 602, 603 is or includes sulfur, selenium, or tellurium, the dopant of doped regions 604 of metal chalcogen layers 601, 602, 603 is or includes ruthenium, and functional group 612 is or includes a hexafluoroacetylacetone group, a tetramethyl-heptanedionato group, an alkyl group such as a methyl or ethyl group, a carbonyl group, a nitrosyl group, an isocyanide group, an aryl group or a cyclopentadienyl group.

In the example of FIG. 6, hardmask layer 206 has been removed and sacrificial layers 204 protect channel regions 501 from doping. However, in some embodiments, hardmask layer 206 remains. The discussed techniques provide for contact region doping through selective laser treatment. After the stacked 2D nanoribbons (i.e., metal chalcogen layers 301, 302, 303) have been created, with contact region 504 exposed and sacrificial layers 204 and, optionally, hardmask layer 206 covering channel region 501, selective wavelengths (i.e., 532 nm, 335 nm, or 1.6 microns or others) and chemistry (i.e., a chemistry including the dopant that allows cleaving of the dopant from a precursor), selective photochemistry is achieved. The dopant materials are intruded only or solely into contact region 504 of the 2D material (i.e., metal chalcogen layers 301, 302, 303), advantageously allowing for selective doping of metal chalcogen layers 601, 602, 603. Thereby the selective photochemistry reaction (i.e., localized chemistry) occurs only in the area of interest and no damage is caused on neighboring sites.

Returning to FIG. 1, processing continues at operation 106, where a spacer material is deposited, the spacer material is patterned, and the spacer material is optionally recessed. The spacer material may be formed using any suitable technique or techniques. For example, the spacer material may be bulk deposited followed by planarization. In some embodiments, the spacer material is one of hafnium oxide (i.e., includes hafnium and oxygen), silicon nitride (i.e., includes silicon and nitrogen), silicon oxide (i.e., includes silicon and oxygen), silicon oxynitride (i.e., includes silicon, oxygen, and nitrogen), aluminum oxide (i.e., includes aluminum and oxygen; alumina), titanium oxide (i.e., includes titanium and oxygen), titanium nitride (i.e., includes titanium and nitrogen), tantalum nitride (i.e., includes tantalum and nitrogen), ruthenium, or amorphous hexagonal boron nitride (i.e., includes boron and nitrogen; hBN; white graphene).

As discussed below, in some embodiments, the material layers of interest (e.g., the 2D material layers) are recrystallized using local laser treatment. In such embodiments, it may be advantageous that the spacer material is reflective of the selected wavelength of light (i.e., limited spectrum around the selected wavelength) such that the laser treatment may reflect off the spacer material and be directed toward and thereby more readily reach the lower ones of material layers 203. In some embodiments, titanium nitride, tantalum nitride, ruthenium, and amorphous hexagonal boron nitride (i.e., TiN, TaN, Ru, and amorphous hBN) offer the advantages of being selectively etchable with respect to adjacent material layers and being substantially reflective of the laser treatment discussed herein below.

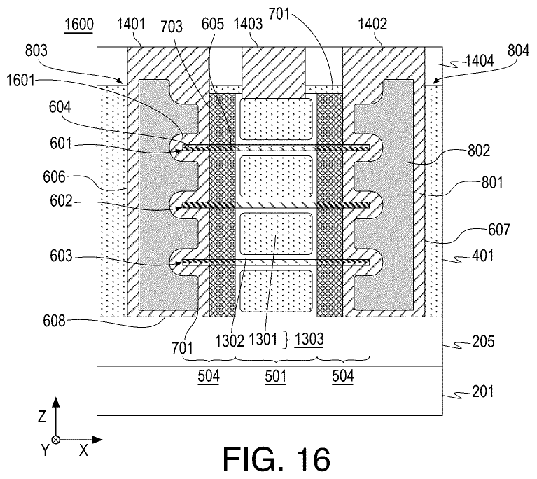

FIG. 7 illustrates a cross-sectional side view of a transistor structure 700 similar to transistor structure 600 after formation of spacer material 701 on doped regions 604. In some embodiments, a bulk spacer material is formed and planarization techniques are used to provide a substantially coplanar top surface. Subsequently, the bulk spacer material may be patterned to form openings 702 and to form spacer material 701 having sidewalls 703 substantially aligned with the outer edges of metal chalcogen layers 601, 602, 603. that expose portions of doped regions 604. In some embodiments, as illustrated herein with respect to FIG. 16, spacer material 701 may be further recessed to provide at least portions of doped regions 604 that jut out beyond the sidewalls 703. Such techniques may provide for additional surface area contact between source and drain contacts and doped regions 604.

Returning to FIG. 1, processing continues at operation 107, where a source and drain contact metal and subsequent fill metal are formed. In some embodiments, the source and drain contact metal are applied using ALD or PVD. The source and drain contact metal may include any suitable metal such as those that provide a suitable work function and low contact resistance. In some embodiments, the source and drain contact metal includes one or more of antimony, bismuth, ruthenium, cobalt, copper, tungsten, gold, silver, or palladium. The fill metal or backfill metal may then be formed using any suitable technique or techniques such as electroplating followed by planarization processing. The fill metal may be any suitable conductive metal such as one or more of cobalt, tungsten, copper, or ruthenium. Although discussed with respect to a liner metal and a fill metal, a single metallization may be used in some embodiments. The single metallization or liner metal and fill metal define a source structure and a drain structure of the transistor.

FIG. 8 illustrates a cross-sectional side view of a transistor structure 800 similar to transistor structure 700 after the deposition of source and drain contact metal 801, and after the bulk metal or backfill metal is deposited and planarized to form fill metal 802. As shown, source and drain contact metal 801 and fill metal 802 define a source structure 803 and a drain structure 804. Furthermore, source and drain contact metal 801 may be substantially conformal to exposed surfaces and fill metal 802 fills the gap of source and drain contact metal 801.

Source structure 803 and drain structure 804 may include any suitable source and drain contact metal 801 and fill metal 802. In some embodiments, source and drain contact metal 801 include one or more of antimony, ruthenium, titanium, or others. Fill metal 802 may include any suitable fill metal such as cobalt, tungsten, copper, ruthenium, or others. As shown, source structure 803 and drain structure 804 are directly on (i.e., in direct contact with) doped regions 604 of metal chalcogen layers 601, 602, 603. Source structure 803 and drain structure 804 are separated from an eventual gate structure by spacer material 701. Furthermore, a gate length L of metal chalcogen layers 601, 602, 603 may be defined as extending between source structure 803 and drain structure 804. In some embodiments, each of metal chalcogen layers 601, 602, 603 has a length L extending between source structure 803 and drain structure 804 of not more than 10 nm. In some embodiments, each of metal chalcogen layers 601, 602, 603 has a length L extending between source structure 803 and drain structure 804 of not more than 7 nm. In some embodiments, each of metal chalcogen layers 601, 602, 603 has a length L extending between source structure 803 and drain structure 804 of between 3 and 10 nm.

Returning to FIG. 1, processing continues at operation 108, where the 2D material layers are recrystallized via localized laser treatment to improve the crystallinity of the 2D material layers. The localized laser treatment is used to apply specific laser wavelength (i.e., 532 nm, 335 nm, or 1.6 microns or others) to heat the nanoribbons (e.g., TMD materials) and recrystallize them to remove defects and to improve crystallinity. The localized laser treatment may be applied at any suitable step in the process flow where the 2D material layers are accessible by the laser and supported by support structures to allow for the anneal and recrystallization without sagging and associated material failures. Furthermore, the 2D material layers may have doped contact regions as discussed with respect to operation 105 or the 2D material layers may be undoped. Notably, the discussed laser treatments (i.e., recrystallization and doping) may be performed separately or together to form transistor structures. In the context of methods 100, localized laser recrystallization is performed after sacrificial material recess, spacer material deposition, and source and contact metallization.

In other contexts, the localized laser recrystallization is applied after patterning the multilayer stack of 2D material layers and interleaved sacrificial material layers or prior to formation of source and drain metallization. In such contexts, the optional hardmask (if deployed) is removed prior to application of the localized laser recrystallization. For example, with reference to FIG. 3, localized laser recrystallization may be applied to metal chalcogen layers 301, 302, 303 and sacrificial layers 204 (after removal of optional hardmask layer 206). As discussed, sacrificial layers may be advantageously translucent (i.e., SiN, SiO2, SiOxNy, Al2O3, or TiO2) to the applied laser treatment to allow for the recrystallization of all of metal chalcogen layers 301, 302, 303, with metal chalcogen layer 303 being more difficult to reach with the laser treatment. Such embodiments offer the ability to access metal chalcogen layers 301, 302, 303, however the transistor structures are not yet fully formed and, the transistor structures being fully formed offers the advantage of more predictable processing.

With reference to FIG. 7, localized laser recrystallization may be applied to metal chalcogen layers 601, 602, 603 (or metal chalcogen layers 301, 302, 303 if contact region doping is not deployed) and sacrificial layers 204 in the presence of spacer material 701 (but absent source structure 803 and a drain structure 804). As discussed, sacrificial layers may be advantageously translucent (i.e., SiN, SiO2, SiOxNy, Al2O3, or TiO2) and spacer material 701 may be advantageously reflective (i.e., TiN, TaN, Ru, hBN) to the applied laser treatment to bring more laser intensity to the lower ones of metal chalcogen layers 601, 602, 603 (or metal chalcogen layers 301, 302, 303). Such embodiments offer the ability to access metal chalcogen layers 601, 602, 603 (or metal chalcogen layers 301, 302, 303) in a manner similar to those discussed below but protect source structure 803 and a drain structure 804, however the transistor structures are not yet fully formed.

As discussed, the localized laser treatment may be applied immediately after the stacked 2D nanoribbons (e.g., TMD material layers) have been created (in the absence of hardmask material) or later in the process flow. In either case, the stack of 2D nanoribbons (e.g., TMD material layers) are exposed to a specific laser wavelength (i.e., limited spectrum around the selected wavelength) to heat the ribbons (e.g., TMD material layers). Transparent or translucent materials (such as oxides or other translucent materials) are deployed between the stacked 2D materials (e.g., TMD material layers), so only the 2D materials substantially absorb the heat enabling it to recrystallize into a high-quality material. Advantageously, the recrystallization is achieved in one step rather than multiple operations.

For example, a multilayer stack including a number of material layers interleaved with a number of sacrificial layers may be fabricated or received, such that the material layers each include a transition metal and a chalcogen, as discussed above. A localized laser treatment may then be applied the multilayer stack such that the localized laser treatment includes recrystallizing each of the material layers of the multilayer stack using the localized laser treatment. In some embodiments, the sacrificial layers are or include a compound of silicon and oxygen (e.g., SiO2), a compound of silicon and nitrogen (e.g., SiN), a compound of silicon, oxygen, and nitrogen (e.g., SiOxNy), a compound of aluminum and oxygen (e.g., Al2O3), or a compound of titanium and oxygen (e.g., TiO2). In some embodiments, the localized laser treatment includes application of a laser having a wavelength of about 532 nm, 335 nm, or 1.6 microns.

FIG. 9 illustrates a cross-sectional side view of a transistor structure 900 similar to transistor structure 800 during recrystallization of metal chalcogen layers 601, 602, 603. As shown, localized laser treatment 901 is applied to transistor structure 900 to recrystallize metal chalcogen layers 601, 602, 603. Localized laser treatment 901 may deploy any suitable wavelength, such as a laser having a wavelength of 532 nm, 335 nm, or 1.6 microns, at any suitable intensity. Localized laser treatment 901 may be applied only to locations of transistor structures 900 and not to other portions of the workpiece for the sake of efficiency and to reduce damage to other regions of the workpiece.

Metal chalcogen layers 601, 602, 603 are thereby recrystallized to reduce defects and to reduce grain boundaries, as discussed further herein below. Also as shown, the application of localized laser treatment 901 provides for varying intensities 902, 903, 904, 905 that reach lower levels of transistor structure 900 due to the absorption of localized laser treatment 901. As discussed, by deploying sacrificial layers 204 that are translucent and spacer material 701 that is reflective, the intensities 902, 903, 904, 905 can be increased to improve recrystallization of lower ones of metal chalcogen layers 601, 602, 603, such as metal chalcogen layer 603. For example, reflections 915 of the laser off of spacer material 701 improves the intensities 902, 903, 904, 905 relative to absorbing or translucent spacer materials. In some embodiments, spacer material 701 is or includes ruthenium or spacer material 701 is or includes a compound of boron and nitrogen (i.e., amorphous hBN), a compound of titanium and nitrogen (i.e., TiN), or a compound of tantalum and nitrogen (i.e., TaN).

However, it is noted that recrystallization of lower ones of metal chalcogen layers 601, 602, 603 may not be as complete as recrystallization of higher ones of metal chalcogen layers 601, 602, 603 due to the inherent different processing conditions. For example, lower metal chalcogen layer 603 may retain more defects such as grain boundary defects with respect to metal chalcogen layer 601 and even metal chalcogen layer 602. This effect may be seen with two, three, or more metal chalcogen layers 601, 602, 603. Such resultant defects such as grain boundary defects are discussed further herein below.

Also as shown, application of localized laser treatment 901 may further impact other regions of transistor structure 900. For example, a region 907 of dielectric layer 205 (or of substrate 201) may have a different morphology relative to a region 908 of dielectric layer 205 (or of substrate 201) due to application of localized laser treatment 901. In some embodiments, region 907 extends into substrate 201. Similarly, regions 912 of spacer material 701 may have a different morphology relative to regions 913 of spacer material 701 due to application of localized laser treatment 901. For example, even when spacer material 701 is a reflective material, some laser energy is absorbed to change the morphology of spacer material 701. In some embodiments, region 907 has a first morphology different than a second morphology of region 908, with the morphology difference being between a crystalline material and an amorphous material, between a polycrystalline material and an amorphous material, or between a crystalline material and a polycrystalline material. In some embodiments, region 912 has a first morphology different than a second morphology of region 913, with the morphology difference being between a crystalline material and an amorphous material, between a polycrystalline material and an amorphous material, or between a crystalline material and a polycrystalline material. As used herein, the term crystalline material indicates a material having highly ordered microscopic structure forming a crystal lattice, the term polycrystalline material indicates a material composed of many microscopic crystals (e.g., crystallites), and the term amorphous material indicates a material that has no periodic arrangement.

As discussed, the laser-based contact region doping and laser-based recrystallization processing may be performed together (as shown in FIG. 9) or separately. In some embodiments, recrystallization processing is provided absent doped contact regions. Similarly, metal chalcogen layers formed using other processes may be recrystallized with the same similar resultant characteristics of the metal chalcogen layers after recrystallization. FIG. 10 illustrates laser-based recrystallization absent doped contact regions. FIGS. 11A-11E illustrate alternative context for laser-based recrystallization, and resultant features of the recrystallized metal chalcogen layers. It is noted the resultant features (i.e., grain boundary defect counts, grain sizes, etc.) of the recrystallized metal chalcogen layers, although illustrated in the context of FIGS. 11A-11E may be achieved using any processing discussed herein such as those discussed with respect to FIGS. 9 and 10, or laser-based recrystallization processing applied to structures discussed with respect to FIGS. 3 and 7.

FIG. 10 illustrates a cross-sectional side view of a transistor structure 1000 similar to transistor structure 900 during recrystallization of metal chalcogen layers 301, 302, 303 to form metal chalcogen layers 1001, 1002, 1003, which are absent doped contact regions. As shown, localized laser treatment 901 is applied to transistor structure 1000 to recrystallize metal chalcogen layers 301, 302, 303. Localized laser treatment 901 and other components of transistor structure 1000 may have any characteristics discussed above with respect to FIG. 9. Similarly, metal chalcogen layers 1001, 1002, 1003 may have any characteristics discussed with respect to other recrystallized metal chalcogen layers, absent doped regions 604.

FIG. 11A illustrates an isometric view of a transistor structure 1100 including scaffolding support structures 1101 and growth structures 1102 extending between scaffolding support structures 1101. In some embodiments, a distance in the x-direction between support structures 1101 (i.e., the length of growth structures 1102 extending between support structures 1101) is about 25 nm and the x-direction width of support structures 1101 is about 5 nm. Scaffolding support structures 1101 and growth structures 1102 may include any suitable materials. In some embodiments, scaffolding support structures 1101 are any of the materials discussed with respect to spacer material 701 and growth structures 1102 are any of the materials discussed with respect to sacrificial layers 204. Transistor structure 1100 may be fabricated using any suitable technique or techniques. Notably, the transistor structures of FIGS. 11A-11E offer another technique for fabricating metal chalcogen layers that may be deployed in the context of a resultant transistor structure.

FIG. 11B illustrates an isometric view of a transistor structure 1110 similar to transistor structure 1100 after formation of metal chalcogen materials 1111 on growth structures 1102. Metal chalcogen materials 1111, which may be TMD or 2D material layers, may by any materials discussed with respect to material layers 203. For example, material layers 203 or metal chalcogen materials 1111, during their growth may include particular characteristics including undesirable grain boundaries 1112 and a characteristic grain size (not shown).

FIG. 11C illustrates an isometric view of a transistor structure 1120 similar to transistor structure 1110 after removal of sidewalls or vertical structures of metal chalcogen materials 1111 to form metal chalcogen layers 1121, 1122, 1123. Metal chalcogen layers 1121, 1122, 1123, which may be TMD or 2D material layers, may have any characteristics discussed with respect to metal chalcogen layers 1121, 1122, 1123. For example, material layers 203 or metal chalcogen layers 1121, 1122, 1123, during their growth may include undesirable grain boundaries 1112 and a characteristic grain size (not shown).

The characteristic grain size of metal chalcogen layers 1121, 1122, 1123 may be determined using any suitable technique or techniques. In some embodiments, a surface of the material layer is analyzed, a number of grains are measured, and an average of the measurements is determined. Any number of grains may be measured such as not fewer than 3, not fewer than 5, or more. The measurement of each grain may be the greatest width of the grain, the median width of the grain, or the like. In some embodiments, a surface of the material layer is analyzed, not fewer than 3 grains are measured to determine their greatest width, and the average of the grain widths is the characteristic grain size (GS).

Similarly, grain boundaries may be expressed as a total grain count for each material layer, as a grain boundary density (grain boundaries per unit area) or the like. Grain boundaries are identified as an interface between two grains or crystallites of a material. It is noted that in the context of metal chalcogen layers and other TMD and 2D materials discussed herein, grain boundaries are relatively rare particularly after recrystallization processing. As used herein, the term grain boundary density indicates a grain boundary count per unit area and may be defined in terms of grain count per square nm. To determine a grain boundary density for each of metal chalcogen layers 1121, 1122, 1123, a number of grains on a top surface or on all surfaces may be determined by identifying grains as boundaries between crystallites. In some embodiments, only grains of a particular length (e.g., not less than 3 nm) qualify as counted grains. The grain count is then taken as a ratio to the total are of the surface analyzed to determine the grain boundary density. In some embodiments, an entirety of a surface is analyzed. In some embodiments, a representative portion of a surface is analyzed. For example, with reference to metal chalcogen layers 1121, 1122, 1123, top of metal chalcogen layers 1121 may have 2 grain boundaries, the middle of metal chalcogen layers 1122 may have 4 grain boundaries, and the bottom of metal chalcogen layers 1123 may have 3 grain boundaries. The grain boundary counts may be divided by the total area of each metal chalcogen layers 1121, 1122, 1123 to determine the grain boundary density. Although illustrated with respect to 2, 4, and 3 grain boundaries, metal chalcogen layers 1121, 1122, 1123 may have any number of grain boundaries.

FIG. 11D illustrates an isometric view of a transistor structure 1130 similar to transistor structure 1130 during and after recrystallization of metal chalcogen layers 1121, 1122, 1123. As discussed, localized laser treatment 901 is applied to transistor structure 1130 to recrystallize metal chalcogen layers 1121, 1122, 1123. Localized laser treatment 901 may deploy any suitable wavelength and characteristics discussed herein. It is noted that in the presence of sacrificial layers 204 or in their absence, similar resultant recrystallization structures may be formed using localized laser treatment 901. As shown, ideally and in some contexts, undesirable grain boundaries 1112 are completely removed using localized laser treatment 901.

FIG. 11E illustrates an isometric view of a transistor structure 1140 similar to transistor structure 1120 after recrystallization of metal chalcogen layers 1121, 1122, 1123 where some undesirable grain boundaries 1112 remain. In some embodiments, localized laser treatment 901 may provide a greater anneal and recrystallization (e.g., higher temperature or higher temperature for a greater duration) of metal chalcogen layer 1121 relative to that of metal chalcogen layers 1122, 1123. Similarly, localized laser treatment 901 may provide a greater anneal and recrystallization of metal chalcogen layer 1122 relative to that of metal chalcogen layer 1123. In the same manner, higher level metal chalcogen layers receive a greater anneal and recrystallization (e.g., higher temperature or higher temperature for a greater duration) than those underlying metal chalcogen layers.

In some embodiments, the resultant grain boundary densities GBD1, GBD2, GBD3 increase 1145 moving down the stack of metal chalcogen layers 1121, 1122, 1123. In some embodiments, grain boundary density GBD1 of metal chalcogen layer 1121 is greater than grain boundary density GBD2 of metal chalcogen layer 1122. In some embodiments, grain boundary density GBD1 of metal chalcogen layer 1121 is greater than grain boundary density GBD3 of metal chalcogen layer 1123. In some embodiments, grain boundary density GBD1 of metal chalcogen layer 1121 is greater than both grain boundary density GBD2 of metal chalcogen layer 1122 and grain boundary density GBD3 of metal chalcogen layer 1123. In some embodiments, In some embodiments, grain boundary density GBD2 of metal chalcogen layer 1122 is greater than grain boundary density GBD3 of metal chalcogen layer 1123. In some embodiments, increase 1145 is a monotonically increasing function across any number of grain boundary densities GBDx from x=1 to x=N where N is the number of metal chalcogen layers 1121, 1122, 1123.

Again, it is noted that increase 1145 of grain boundary densities GBD1, GBD2, GBD3 described with respect to metal chalcogen layers 1121, 1122, 1123 may be evident in any stack of metal chalcogen layers subject to top-down localized laser anneal processing. For example, increase 1145 and grain boundary densities GBD1, GBD2, GBD3 may be evident in metal chalcogen layers 601, 602, 603 (when subject to localized laser treatment 901 as discussed with respect to FIG. 8), or metal chalcogen layers 1001, 1002, 1003 (when subject to localized laser treatment 901 as discussed with respect to FIG. 10). With reference to FIG. 10, In some embodiments, a plurality of material layers (e.g., metal chalcogen layers 1001, 1002, 1003) metal each include a transition metal and a chalcogen and each have channel region 501. In some embodiments, the material layers include a first material layer (e.g., metal chalcogen layer 1001 or metal chalcogen layer 1002) over a second material layer (e.g., metal chalcogen layer 1002 or metal chalcogen layer 1003), the first material layer having a first grain boundary density (GBD1 or GBD2) that is less than a second grain boundary density (GBD2 or GBD3) of the second material layer. In some embodiments, the material layers (e.g., metal chalcogen layers 1001, 1002, 1003) include a third material layer (e.g., metal chalcogen layer 1002) between the first material layer (e.g., metal chalcogen layer 1001) and the second material layer (e.g., metal chalcogen layer 1003), the third material layer having a third grain boundary density that is greater than the first grain boundary density and less than the second grain boundary density. In some embodiments, the first grain boundary density is not more than one grain boundary in a total lateral area of the first material layer and the third grain boundary count is not fewer than three grain boundaries in a total lateral area of the second material layer. Other grain boundary densities may be evident in metal chalcogen layers 1001, 1002, 1003.

Discussion now turns to completing fabrication of transistor structures. Such operations may be applied to any stack of 2D material layers discussed herein. In some embodiments, the stack of 2D material layers includes doped contact regions. In some embodiments, the stack of 2D material layers includes recrystallized material layers. In some embodiments, the stack of 2D material layers includes both doped contact regions and recrystallized material layers.

Returning to FIG. 1, processing continues at operation 109, where remaining portions of the sacrificial layers of the multilayer stack are removed. In some embodiments, a patterned photoresist layer is formed and etch techniques are used to selectively remove the sacrificial layers of the multilayer stack, and the photoresist layer is then removed.

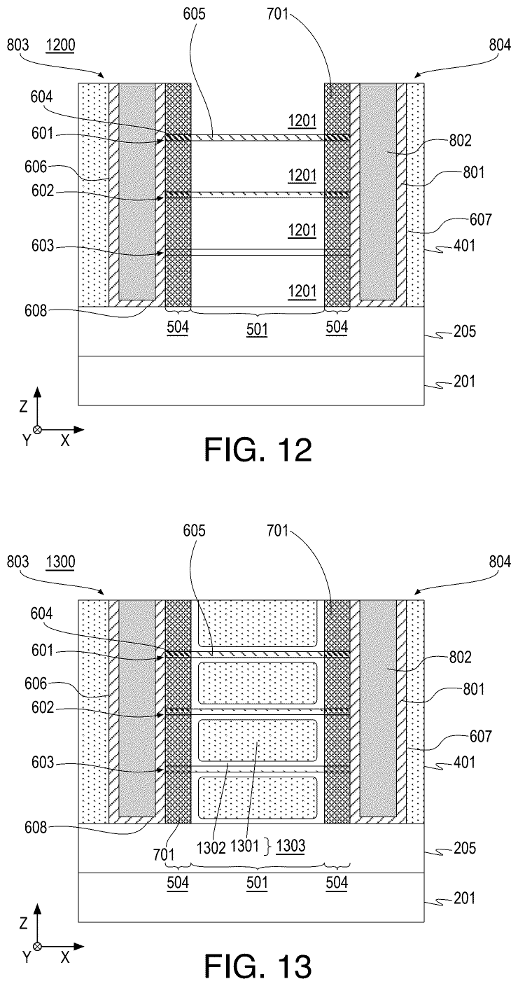

FIG. 12 illustrates a cross-sectional side view of a transistor structure 1200 similar to transistor structure 900 after removal of the remaining portions of sacrificial layers 204 to provide gate structure openings 1201. In some embodiments, a patterned layer is formed over transistor structure 1200, sacrificial layers 204 are removed by selective wet etch techniques, and the patterned layer is removed. In contexts where hardmask layer 206 remains (refer to FIG. 4), access to sacrificial layers 204 is provided by patterned openings in dielectric material 401 that are into or out of the page (i.e., in the positive or negative y-dimension) relative to the view shown in FIG. 12 and sacrificial layers 204 are removed by selective wet etch techniques using the openings. As shown, metal chalcogen layers 601, 602, 603 are free standing but supported by spacer material 701.

Returning to FIG. 1, processing continues at operation 110, where gate structures are formed within the openings vacated by the removal of the remaining portions of the sacrificial layers at operation 109. In some embodiments, the gate structure includes a gate dielectric layer and gate electrode. The gate dielectric layer may be formed by conformal deposition using ALD, for example. Similarly, the gate electrode (e.g., gate metal) may be formed using deposition techniques including ALD, plating techniques, or the like. Such gate dielectric layer and gate electrode deposition may then be followed by planarization techniques.

FIG. 13 illustrates a cross-sectional side view of a transistor structure 1300 similar to transistor structure 1200 after the formation of gate structure 1303, which includes gate dielectric 1302 and gate electrode 1301 such that gate electrode 1301 is separated from metal chalcogen layers 601, 602, 603 by gate dielectric 1302. Gate dielectric 1302 may have a high relative permittivity (i.e., dielectric constant, K). In some high-K gate dielectric embodiments, gate dielectric 1302 is a metal oxide including oxygen and one or more metals, such as, but not limited to, aluminum, hafnium, zirconium, tantalum, or titanium. In some embodiments, gate dielectric 1302 is silicon oxide. Gate electrode 1301 may be or include a metal such as but not limited to platinum, nickel, molybdenum, tungsten, palladium, gold, alloys thereof, or nitrides such as titanium nitride, tantalum nitride, tungsten silicon nitride, or others. In some embodiments, gate electrode 1301 includes a work function metal and a fill metal. After deposition of gate dielectric 1302 and gate electrode 1301, a planarization process is performed to remove the gate dielectric layer and the gate electrode layer from an uppermost surface of transistor structure 1300. As shown, gate structure is directly on and between adjacent ones of metal chalcogen layers 601, 602, 603. Furthermore, source structure 803 and drain structure 804 are coupled to each of metal chalcogen layers 601, 602, 603.

Returning to FIG. 1, processing continues at operation 111, where gate, source, and drain contacts are formed. In some embodiments, after gate formation, an overlying dielectric layer is deposited, and source and drain contact openings are formed in the dielectric layer using lithography and etch techniques. The openings are then filled with a contact metal or metal(s), followed by planarization processing.

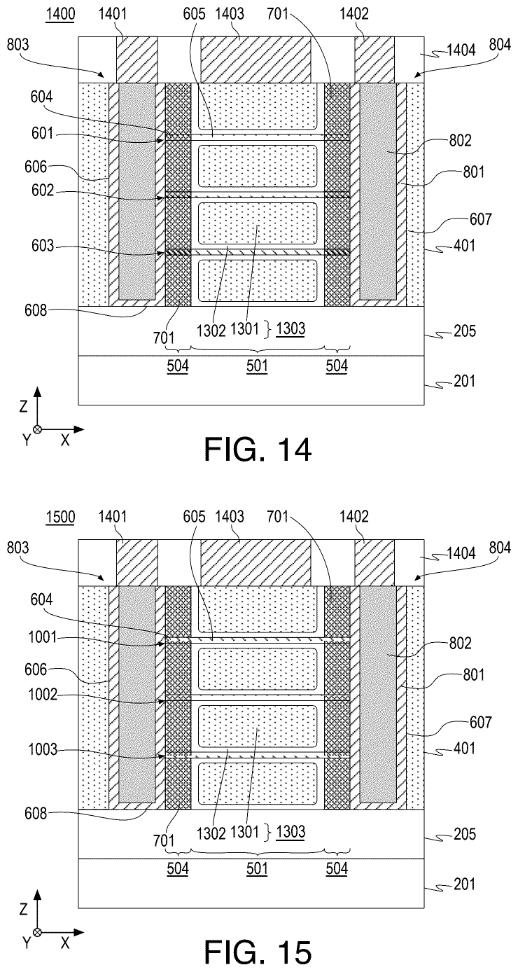

FIG. 14 illustrates a cross-sectional side view of a transistor structure 1400 similar to transistor structure 1300 after the formation of gate contact 1403, source contact 1401, drain contact 1402, and dielectric material 1404. In some embodiments, a bulk dielectric layer is formed over a top surface of transistor structure 1300 and a resist layer is deposited and patterned on the bulk dielectric layer. Etch techniques are then used to form openings corresponding to gate contact 1403, source contact 1401, and drain contact 1402, and the resist layer is removed. The openings are then filled with contact metal and planarization techniques are used to form a planar top surface of transistor structure 1400. In some embodiments, the metal of gate contact 1403, source contact 1401, and drain contact 1402 are the same as that of fill metal 802, however, other metals may be used.

It is noted that, in the context of FIG. 14, metal chalcogen layers 601, 602, 603 may be recrystallized or not. As discussed, in some embodiments, recrystallized metal chalcogen layers 1001, 1002, 1003 may be deployed without contact doping. Furthermore, as discussed with respect to FIG. 7, in some embodiments, the spacer material may be further recessed to provide at least portions of doped regions of the metal chalcogen layers that jut out beyond the sidewalls spacer material for additional surface area contact between source and drain contacts and the doped regions of the metal chalcogen layers.

FIG. 15 illustrates a cross-sectional side view of a transistor structure 1500 similar to transistor structure 1400 but deploying metal chalcogen layers 1001, 1002, 1003 (or metal chalcogen layers 1121, 1122, 1123). Transistor structure 1500 and the components thereof may have the same or similar features or characteristics as those discussed elsewhere herein.

FIG. 16 illustrates a cross-sectional side view of a transistor structure 1600 similar to transistor structure 1400 but having an additional recess of spacer material 701. With reference to FIG. 7, further recess of spacer material 701 (illustrated in FIG. 16 inclusive of a narrower channel region 501) provides for portions 1601 of doped regions 604 that jut out beyond sidewalls 703 of spacer material 701. Such techniques may provide for additional surface area contact between source structure 803 and drain structure 804 with doped regions 604. With reference to FIG. 7, after additional recess of spacer material 701, processing may continue in the same manner to form transistor structure 1600 or a transistor structure similar to transistor structure 1600 with undoped metal chalcogen layers.

Returning to FIG. 1, processing continues at operation 112, where continued processing is performed as is known in the art. Such processing may include forming interconnect features including metallization routings and vias, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

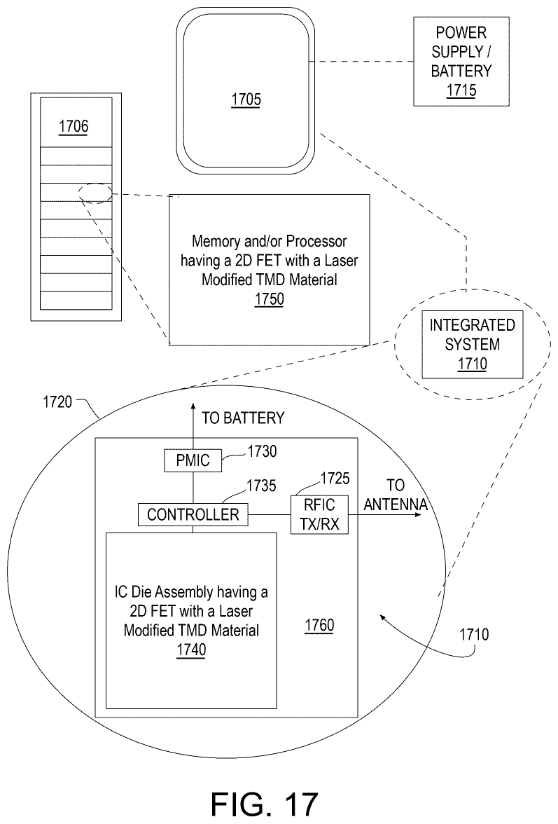

FIG. 17 illustrates exemplary systems employing metal chalcogen material-based transistor structures having recrystallized 2D material layers and/or doped edges of the 2D material layers, in accordance with some embodiments. The system may be a mobile computing platform 1705 and/or a data server machine 1706, for example. Either may employ a monolithic IC die, for example, having a field effect transistor having one or more metal chalcogen layers (e.g., nanoribbons) with recrystallized 2D material layers and/or doped edges as described elsewhere herein. Server machine 1706 may be any commercial server, for example including any number of high-performance computing platforms disposed within a rack and networked together for electronic data processing, which in the exemplary embodiment includes an IC die assembly 1750 with a field effect transistor having one or more metal chalcogen layers (e.g., nanoribbons) with recrystallized 2D material layers and/or doped edges as described elsewhere herein. Mobile computing platform 1705 may be any portable device configured for each of electronic data display, electronic data processing, wireless electronic data transmission, or the like. For example, mobile computing platform 1705 may be any of a tablet, a smart phone, a laptop computer, etc., and may include a display screen (e.g., a capacitive, inductive, resistive, or optical touchscreen), a chip-level or package-level integrated system 1710, and a battery/power supply 1715. Although illustrated with respect to mobile computing platform 1705, in other examples, chip-level or package-level integrated system 1710 and a battery/power supply 1715 may be implemented in a desktop computing platform, an automotive computing platform, an internet of things platform, or the like. As discussed below, in some examples, the disclosed systems may include a sub-system 1760 such as a system on a chip (SOC) or an integrated system of multiple ICs, which is illustrated with respect to mobile computing platform 1705.

Whether disposed within integrated system 1710 illustrated in expanded view 1720 or as a stand-alone packaged device within data server machine 1706, sub-system 1760 may include memory circuitry and/or processor circuitry 1740 (e.g., RAM, a microprocessor, a multi-core microprocessor, graphics processor, etc.), a power management integrated circuit (PMIC) 1730, a controller 1735, and a radio frequency integrated circuit (RFIC) 1725 (e.g., including a wideband RF transmitter and/or receiver (TX/RX)). As shown, one or more IC dice, such as memory circuitry and/or processor circuitry 1740 may be assembled and implemented such that one or more have a field effect transistor with one or more metal chalcogen layers (e.g., nanoribbons) with recrystallized 2D material layers and/or doped edges as described herein. In some embodiments, RFIC 1725 includes a digital baseband and an analog front end module further comprising a power amplifier on a transmit path and a low noise amplifier on a receive path). Functionally, PMIC 1730 may perform battery power regulation, DC-to-DC conversion, etc., and so has an input coupled to battery/power supply 1715, and an output providing a current supply to other functional modules. As further illustrated in FIG. 17, in the exemplary embodiment, RFIC 1725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1740 may provide memory functionality for sub-system 1760, high level control, data processing and the like for sub-system 1760. In alternative implementations, each of the SOC modules may be integrated onto separate ICs coupled to a package substrate, interposer, or board. For example, any transistor structure discussed herein may be deployed as part of an IC die that is a component of the systems of FIG. 17.

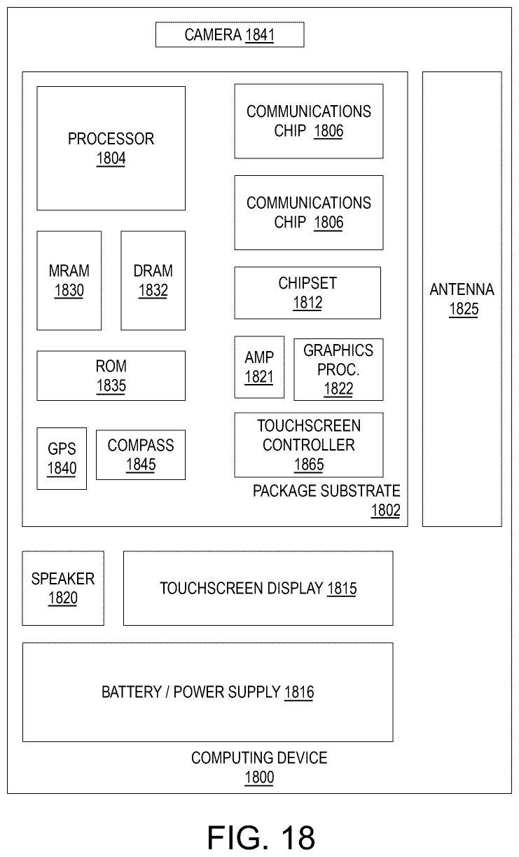

FIG. 18 is a functional block diagram of an electronic computing device 1800, in accordance with some embodiments. For example, device 1800 may, via any suitable component therein, implement a field effect transistor having one or more metal chalcogen layers (e.g., nanoribbons) with recrystallized 2D material layers and/or doped edges as discussed herein. For example, one or more IC dies of electronic computing device 1800 may deploy a GAA transistor having one or more metal chalcogen layers (e.g., nanoribbons) with recrystallized 2D material layers and/or doped edges. Device 1800 further includes a motherboard or package substrate 1802 hosting a number of components, such as, but not limited to, a processor 1804 (e.g., an applications processor). Processor 1804 may be physically and/or electrically coupled to package substrate 1802. In some examples, processor 1804 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 1806 may also be physically and/or electrically coupled to the package substrate 1802. In further implementations, communication chips 1806 may be part of processor 1804. Depending on its applications, computing device 1800 may include other components that may or may not be physically and electrically coupled to package substrate 1802. These other components include, but are not limited to, volatile memory (e.g., DRAM 1832), non-volatile memory (e.g., ROM 1835), flash memory (e.g., NAND or NOR), magnetic memory (MRAM 1830), a graphics processor 1822, a digital signal processor, a crypto processor, a chipset 1812, an antenna 1825, touchscreen display 1815, touchscreen controller 1865, battery/power supply 1816, audio codec, video codec, power amplifier 1821, global positioning system (GPS) device 1840, compass 1845, accelerometer, gyroscope, speaker 1820, camera 1841, and mass storage device (such as hard disk drive, solid-state drive (SSD), compact disk (CD), digital versatile disk (DVD), and so forth, or the like.

Communication chips 1806 may enable wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1806 may implement any of a number of wireless standards or protocols, including, but not limited to, those described elsewhere herein. As discussed, computing device 1800 may include a plurality of communication chips 1806. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 1816 may include any suitable power supply circuitry and, optionally, a battery source to provide power to components of electronic computing device 1800.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a plurality of material layers each comprising a transition metal and a chalcogen and each having a channel region, such that the material layers comprise a first material layer over a second material layer, the first material layer having a first grain boundary density that is less than a second grain boundary density of the second material layer, a gate structure directly on and between the channel regions, and a source structure and a drain structure coupled to each of the material layers.

In one or more second embodiments, further to the first embodiments, the material layers comprise a third material layer between the first material layer and the second material layer, the third material layer having a third grain boundary density that is greater than the first grain boundary density and less than the second grain boundary density.

In one or more third embodiments, further to the first or second embodiments, the first grain boundary density is not more than one grain boundary in a total lateral area of the first material layer and the third grain boundary count is not fewer than three grain boundaries in a total lateral area of the second material layer.

In one or more fourth embodiments, further to the first through third embodiments, each of the material layers has a length extending between the source structure and the drain structure of not more than 10 nm.

In one or more fifth embodiments, further to the first through fourth embodiments, the apparatus further comprises a spacer material between the gate structure and the source structure or the drain structure, such that the spacer comprises ruthenium or a compound of boron and nitrogen, titanium and nitrogen, or tantalum and nitrogen.

In one or more sixth embodiments, further to the first through fifth embodiments, each of the material layers comprises a second region between the channel region and the source structure or the drain structure, the second regions comprising a dopant absent from the channel regions.

In one or more seventh embodiments, further to the first through sixth embodiments, the transition metal comprises molybdenum or tungsten, the chalcogen comprises sulfur, selenium, or tellurium, and the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

In one or more eighth embodiments, further to the first through seventh embodiments, the apparatus further comprises a substrate under the material layers, such that the substrate comprises a first region adjacent to the material layers and a second region distal from the material layers, the first region having a first morphology different than a second morphology of the second region.

In one or more ninth embodiments, further to the first through eighth embodiments, the apparatus further comprises an integrated circuit (IC) die comprising a transistor comprising the material layers, the gate structure, the source structure, and the drain structure, and a power supply coupled to the IC die.

In one or more tenth embodiments, a system comprises an IC die including a transistor structure according to any of the apparatuses of the first through ninth embodiments, and one of a power supply or a display coupled to the IC die.

In one or more eleventh embodiments, an apparatus comprises a plurality of material layers each comprising a transition metal and a chalcogen and each having a channel region, a structure adjacent the material layers, a gate structure directly on and between the channel regions, and a source structure and a drain structure coupled to each of the material layers, such that the source structure or the drain structure is on the structure, each of the material layers comprises a second region between the channel region and the source structure or the drain structure, the second regions comprise a dopant absent from the channel regions, and the structure comprises a molecule comprising the dopant bonded to a functional group.

In one or more twelfth embodiments, further to the eleventh embodiments, the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

In one or more thirteenth embodiments, further to the eleventh or twelfth embodiments, the functional group comprises one of a hexafluoroacetylacetone group, a tetramethyl-heptanedionato group, an alkyl group, a carbonyl group, a nitrosyl group, an isocyanide group, an aryl group, or a cyclopentadienyl group.

In one or more fourteenth embodiments, further to the eleventh through thirteenth embodiments, the transition metal comprises molybdenum or tungsten, the chalcogen comprises sulfur, selenium, or tellurium, the dopant comprises ruthenium, and the functional group comprises one of a hexafluoroacetylacetone group, a tetramethyl-heptanedionato group, an alkyl group, a carbonyl group, a nitrosyl group, an isocyanide group, an aryl group, or a cyclopentadienyl group.

In one or more fifteenth embodiments, further to the eleventh through fourteenth embodiments, the structure comprises a dielectric material, the functional group comprises a carbonyl group, and the molecule is on a surface of the dielectric material.

In one or more sixteenth embodiments, further to the eleventh through fifteenth embodiments, the molecule is between the dielectric material and a liner material of the source structure or the drain structure, the source structure or the drain structure further comprising a fill metal on the liner material.

In one or more seventeenth embodiments, further to the eleventh through sixteenth embodiments, the apparatus further comprises an integrated circuit (IC) die comprising a transistor comprising the material layers, the gate structure, the source structure, and the drain structure, and a power supply coupled to the IC die.

In one or more eighteenth embodiments, a system comprises an IC die including a transistor structure according to any of the apparatuses of the eleventh through seventeenth embodiments, and one of a power supply or a display coupled to the IC die.

In one or more nineteenth embodiments, a method comprises receiving a multilayer stack comprising a plurality of material layers interleaved with a plurality of sacrificial layers, such that the material layers each comprise a transition metal and a chalcogen, applying a localized laser treatment to the multilayer stack, the localized laser treatment comprising recrystallizing each of the material layers of the multilayer stack using the localized laser treatment, or doping an exposed region of each of the material layers using the localized laser treatment and a precursor comprising a dopant, and coupling a source structure, a drain structure, and a gate structure to the material layers.

In one or more twentieth embodiments, further to the nineteenth embodiments, the localized laser treatment comprises recrystallizing each of the material layers, the sacrificial layers comprise silicon and oxygen, silicon and nitrogen, aluminum and oxygen, or titanium and oxygen, and the localized laser treatment comprises application of a laser having a wavelength of about 532 nm, 335 nm, or 1.6 microns.

In one or more twenty-first embodiments, further to the nineteenth or twentieth embodiments, the localized laser treatment comprises doping the exposed region of each of the material layers, such that the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

In one or more twenty-second embodiments, further to the nineteenth through twenty-first embodiments, the precursor comprises one of a hexafluoroacetylacetone group, a tetramethyl-heptanedionato group, an alkyl group, a carbonyl group, a nitrosyl group, an isocyanide group, an aryl group, or a cyclopentadienyl group.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a plurality of material layers each comprising a transition metal and a chalcogen and each having a channel region, wherein the material layers comprise a first material layer over a second material layer, the first material layer having a first grain boundary density that is less than a second grain boundary density of the second material layer;
a gate structure directly on and between the channel regions; and
a source structure and a drain structure coupled to each of the material layers.

2. The apparatus of claim 1, wherein the material layers comprise a third material layer between the first material layer and the second material layer, the third material layer having a third grain boundary density that is greater than the first grain boundary density and less than the second grain boundary density.

3. The apparatus of claim 2, wherein the first grain boundary density is not more than one grain boundary in a total lateral area of the first material layer and the third grain boundary count is not fewer than three grain boundaries in a total lateral area of the second material layer.

4. The apparatus of claim 3, wherein each of the material layers has a length extending between the source structure and the drain structure of not more than 10 nm.

5. The apparatus of claim 3, further comprising a spacer material between the gate structure and the source structure or the drain structure, wherein the spacer comprises ruthenium or a compound of boron and nitrogen, titanium and nitrogen, or tantalum and nitrogen.

6. The apparatus of claim 1, wherein each of the material layers comprises a second region between the channel region and the source structure or the drain structure, the second regions comprising a dopant absent from the channel regions.

7. The apparatus of claim 6, wherein the transition metal comprises molybdenum or tungsten, the chalcogen comprises sulfur, selenium, or tellurium, and the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

8. The apparatus of claim 1, further comprising:
a substrate under the material layers, wherein the substrate comprises a first region adjacent to the material layers and a second region distal from the material layers, the first region having a first morphology different than a second morphology of the second region.

9. The apparatus of claim 1, further comprising:
an integrated circuit (IC) die comprising a transistor comprising the material layers, the gate structure, the source structure, and the drain structure; and
a power supply coupled to the IC die.

10. An apparatus, comprising:
a plurality of material layers each comprising a transition metal and a chalcogen and each having a channel region;
a structure adjacent the material layers;
a gate structure directly on and between the channel regions; and
a source structure and a drain structure coupled to each of the material layers, wherein the source structure or the drain structure is on the structure, each of the material layers comprises a second region between the channel region and the source structure or the drain structure, the second regions comprise a dopant absent from the channel regions, and the structure comprises a molecule comprising the dopant bonded to a functional group.

11. The apparatus of claim 10, wherein the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

12. The apparatus of claim 11, wherein the functional group comprises one of a hexafluoroacetylacetone group, a tetramethyl-heptanedionato group, an alkyl group, a carbonyl group, a nitrosyl group, an isocyanide group, an aryl group, or a cyclopentadienyl group.

13. The apparatus of claim 10, wherein the transition metal comprises molybdenum or tungsten, the chalcogen comprises sulfur, selenium, or tellurium, the dopant comprises ruthenium, and the functional group comprises one of a hexafluoroacetylacetone group, a tetramethyl-heptanedionato group, an alkyl group, a carbonyl group, a nitrosyl group, an isocyanide group, an aryl group, or a cyclopentadienyl group.

14. The apparatus of claim 10, wherein the structure comprises a dielectric material, the functional group comprises a carbonyl group, and the molecule is on a surface of the dielectric material.

15. The apparatus of claim 14, wherein the molecule is between the dielectric material and a liner material of the source structure or the drain structure, the source structure or the drain structure further comprising a fill metal on the liner material.

16. The apparatus of claim 10, further comprising:
an integrated circuit (IC) die comprising a transistor comprising the material layers, the gate structure, the source structure, and the drain structure; and
a power supply coupled to the IC die.

17. A method, comprising
receiving a multilayer stack comprising a plurality of material layers interleaved with a plurality of sacrificial layers, wherein the material layers each comprise a transition metal and a chalcogen;
applying a localized laser treatment to the multilayer stack, the localized laser treatment comprising:
recrystallizing each of the material layers of the multilayer stack using the localized laser treatment, or
doping an exposed region of each of the material layers using the localized laser treatment and a precursor comprising a dopant; and
coupling a source structure, a drain structure, and a gate structure to the material layers.

18. The method of claim 17, wherein the localized laser treatment comprises recrystallizing each of the material layers, the sacrificial layers comprise silicon and oxygen, silicon and nitrogen, aluminum and oxygen, or titanium and oxygen, and the localized laser treatment comprises application of a laser having a wavelength of about 532 nm, 335 nm, or 1.6 microns.

19. The method of claim 17, wherein the localized laser treatment comprises doping the exposed region of each of the material layers, wherein the dopant comprises one of ruthenium, germanium, aluminum, lanthanum, magnesium, vanadium, niobium, tantalum, manganese, rhenium, gallium, antimony, scandium, yttrium, gadolinium, molybdenum, or tungsten.

20. The method of claim 19, wherein the precursor comprises one of a hexafluoroacetylacetone group, a tetramethyl-heptanedionato group, an alkyl group, a carbonyl group, a nitrosyl group, an isocyanide group, an aryl group, or a cyclopentadienyl group.
